(19) United States
(12) Patent Application Publication
(10) Pub. No.: US 2007/0057320 A1
(43) Pub. Date: Mar. 15, 2007

(54) Semiconductor Devices with Stressed Channel Regions and methods Forming the Same

(76) Inventors: Tetsuji Ueno, Gyeonggi-do (KR); Hwa-sung Rhee, Gyeonggi-do (KR); Ho Lee, Chungcheongnam-do (KR)

Correspondence Address: MYERS BIGEL SIBLEY & SAJOVEC, PO BOX 37428, RALEIGH, NC, 27627, US

(21) Appl. No.: 11/426,595

(22) Filed: Jun. 27, 2006

(30) Foreign Application Priority Data
Sep. 12, 2005 (KR) 2005-84657

(51) Int. Cl. H01L 29/76

(52) U.S. Cl. 257/327

(57) ABSTRACT

A semiconductor device includes a substrate having a semiconductor channel region therein. A gate electrode is provided on the channel region. A SiGeC stress-inducing region is provided adjacent the channel region. The SiGeC region is configured to form a semiconductor junction with the channel region and induce a net mobility-enhancing stress in a portion of the channel region. The SiGeC region may have a Ge/C atomic ratio of less than about 12. The SiGeC region also has a sufficient concentration of substitutional C atoms therein to induce a net tensile stress in the portion of the channel region, which has a different lattice constant relative to the SiGeC region.

### REFERENCE TO PRIORITY PATENT APPLICATION

This application claims the benefit of Korean Patent Application No. 10-2005-0084657, filed Sep. 12, 2005, in the Korean Intellectual Property Office, the disclosure of which is hereby incorporated herein in its entirety by reference.

### FIELD OF THE INVENTION

The present invention relates to semiconductor devices and methods of forming same.

### BACKGROUND OF THE INVENTION

Methods of improving electron or hole mobility in a channel region of a transistor by applying stress to the channel region are known. A silicon (Si) layer can be stressed when the Si layer is contacted with a Si-based material layer having a different lattice constant than the Si layer. When this occurs, the electron or hole mobility may be improved in response to a change in an energy band structure of the stressed Si layer.

To apply a stress to the channel region of the Si layer, the Si-based material having a different lattice constant than the Si layer may be grown on the surface of a semiconductor substrate having a source/drain region or a gate electrode formed therein. When the Si-based material layer is grown in the source/drain region, the stress can be directly applied to the channel region of the Si layer and a doping profile of dopants can be controlled. A silicon germanium (SiGe) layer can be formed to induce a compressive stress to the Si layer, while a silicon carbide (SiC) layer can be formed to induce a tensile stress to the Si layer. When a compressive stress is applied to the channel region of the Si layer, the electron mobility of the channel region is improved.

FIG. 1 is a sectional view of a conventional SiC semiconductor device. Referring to FIG. 1, an active region including a channel region is defined by device isolation layers 12 in a semiconductor substrate 10. A gate electrode 18 is formed on the semiconductor substrate 10 with a gate insulating layer interposed therebetween. In addition, insulating spacers 20 may be formed on sidewalls of the gate electrode 18. Source/drain regions 14 formed of SiC are formed in the substrate 10, on both sides of the gate electrode 18. The channel region is disposed between the SiC source/drain regions 14.

The SiC source/drain region 14 induces a tensile stress to the channel region (at a portion “a”), and a carbon (C) concentration is generally about 1% or less. However, the conventional SiC semiconductor device has some problems. In order to generate the tensile stress by SiC, the carbon must be a solid solution as a substitute for a Si lattice site. The reason for this is that when the carbon is a solid solution located in a space between the Si lattice sites (i.e., the carbon (c) is interstitial), it generates a compressive stress rather than a tensile stress, which degrades the mobility of change carriers (e.g., electrons) within the channel region. Additionally, the chemical vapor deposition (CVD) of SiC must be performed at about 600° C. for the substitution of the carbon to occur. However, it takes a long time of about 10-60 minutes to grow the SiC to a thickness of about 500 Å because SiC has a growth rate of only about 0.1 Å/sec at about 600° C.

### SUMMARY OF THE INVENTION

Embodiments of the present invention include semiconductor devices having stressed semiconductor regions therein that are located within a current path of the device. According to some of these embodiments, a field effect transistor includes a substrate having a semiconductor channel region therein. This substrate may be a silicon substrate and the channel region may be a silicon channel region of N-type or P-type conductivity. A gate electrode is provided on the channel region. This gate electrode may be an insulated gate electrode having an electrically insulating layer (e.g., gate oxide layer) extending directly on a surface of the channel region. A SiGeC stress-inducing region is also provided adjacent the channel region. In particular, the SiGeC region is configured to form a semiconductor junction with the channel region and induce a net mobility-enhancing stress in a portion of the channel region. In these embodiments, the SiGeC region may have a Ge/C atomic ratio of less than about 12. The SiGeC region also has a sufficient concentration of substitutional C atoms therein to induce a net tensile stress in the portion of the channel region, which has a different lattice constant relative to the SiGeC region.

According to some of these embodiments, a concentration of C atoms in the SiGeC region is in a range between about 0.5 atomic % and about 2.0 atomic % and a concentration of Ge atoms in the SiGeC region is in a range between about 6 atomic % and about 24 atomic %. The SiGeC region may be formed as a pair of relatively highly doped source and drain regions, which form P-N rectifying junctions with opposites sides of the channel region.

Still further embodiments of the invention include methods of forming field effect transistors by forming a gate electrode on a surface of a semiconductor substrate having a semiconductor channel region therein extending opposite the gate electrode. The surface of the semiconductor substrate is selectively etched to define source and drain region trenches therein on opposite sides of the channel region. A step is then performed to form source and drain regions, comprising SiGeC, in the source and drain region trenches, respectively. These source and drain regions are formed to have a sufficient concentration of substitutional C atoms therein to thereby induce a net tensile stress in portions of the channel region extending opposite the gate electrode. This step of forming the source and drain regions may include depositing SiGeC regions into the source and drain region trenches at a temperature in a range from about 550° C. to about 700° C. This step of depositing SiGeC regions into the source and drain region trenches may also include depositing SiGeC regions into the source and drain region trenches while simultaneously injecting source and drain region dopants into the deposited SiGeC regions. This step of forming the source and drain regions may also be preceded by a step of injecting source and drain region dopants into the semiconductor substrate. In addition, the step of depositing SiGeC regions into the source and drain region trenches may include depositing SiGeC using a silicon-based source gas selected from a group consisting of SiCl₂H₂, SiH₄ and Si₂H₆ and/or using a germanium-based source gas comprising GeH₄. The source and drain region trenches may also be exposed to an HCl gas, which may operate to enhance growth selectivity.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view of a conventional SiC semiconductor device;

FIGS. 2A through 2D are schematic views illustrating a temperature dependency during a process of forming a SiGeC layer according to an embodiment of the present invention;

FIG. 2E is a graph illustrating a relationship between the amount of substituted carbon and a growth rate of a SiGeC layer;

FIG. 3 is a graph illustrating a growth rate of a SiGeC layer according to a concentration of Ge; and

FIGS. 4 through 6 are sectional views illustrating methods of manufacturing a semiconductor device having SiGeC regions therein, according to embodiments of the present invention.

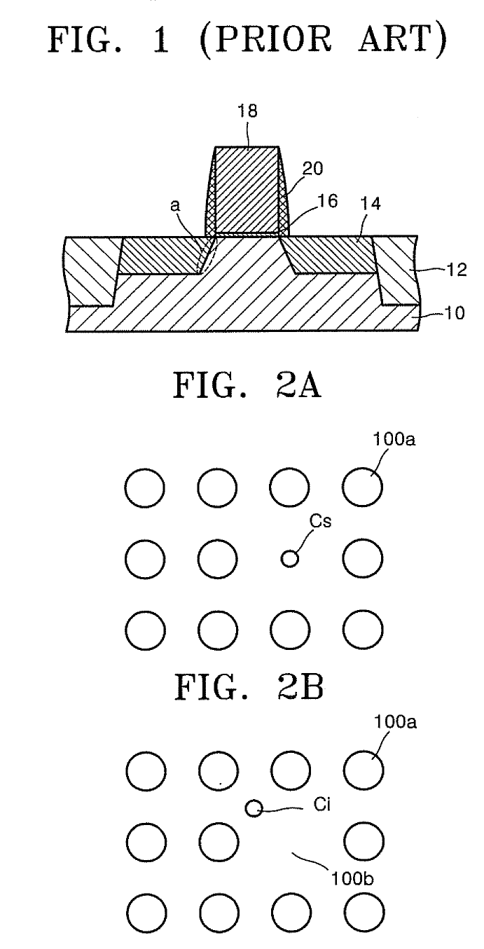

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their description will be omitted.

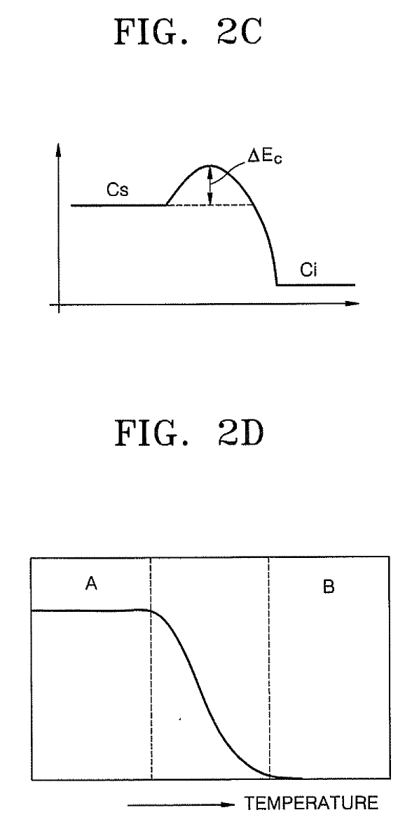

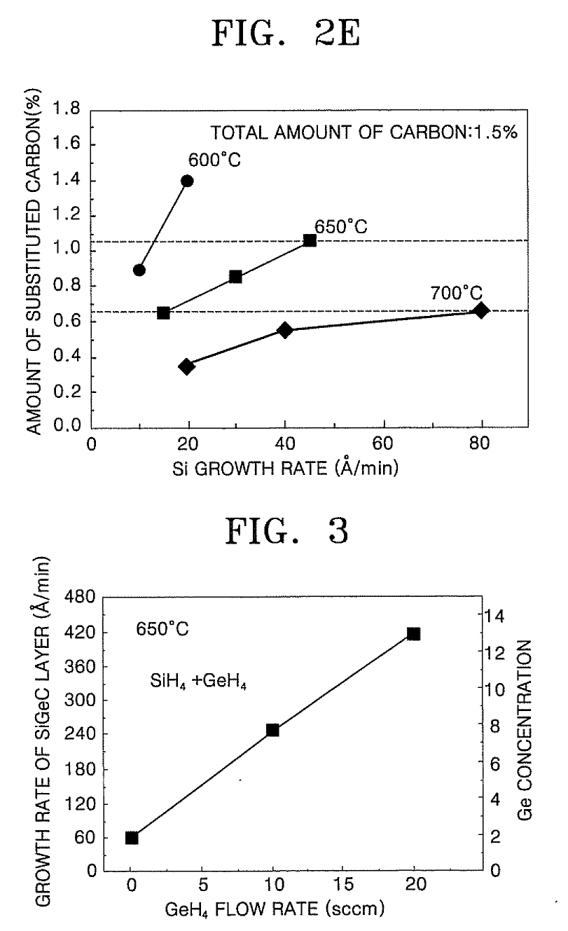

FIGS. 2A through 2D are schematic views illustrating a temperature dependency during a process of forming a SiGeC layer, according to an embodiment of the present invention. FIG. 2E is a graph illustrating a relationship between the amount of substituted carbon and a growth rate of a SiGeC layer. FIG. 2A illustrates carbon (Cs) substituted for a Si lattice site 100a, and FIG. 2B illustrates interstitial carbon (Ci) within a space between Si lattice sites 100a. A carbon atom occupies a smaller space than a silicon atom (about 34.3% smaller than silicon). The substituted carbon Cs is small and thus typically attracts a surrounding Si atom, which generates a tensile stress in a neighboring silicon region. On the contrary, an interstitial carbon atom Ci typically repels surrounding Si atoms to generate a compressive stress in a neighboring silicon region, resulting in a lattice defect 100b. The lattice defect 100b can contribute to a leakage current in a semiconductor device (e.g., transistor, diode, etc.).

FIGS. 2C and 2D are graphs illustrating a state where the substituted carbon Cs is thermally activated and converted into interstitial carbon Ci. Referring to FIGS. 2C and 2D, the carbon Cs is in a substitution-type solid solution at a low temperature state A, while the carbon Ci is in an interstitial-type solid solution at a high temperature state B. An activation energy ΔEc must be overcome to cause carbon atoms to transition from a substitutional state to an interstitial state. Accordingly, it is preferable that an SiGeC layer be formed at the low temperature A to obtain substituted carbon Cs atoms in the SiGeC layer.

Referring to FIG. 2E, the amount of the substituted carbon Cs in the SiGeC layer is set to be about 0.65-1.05 atomic %; however, the substituted carbon Cs amount may be 0.5-2 atomic % depending on the desired characteristics of the semiconductor device. Under the condition that the total amount of applied carbon is 1.5 atomic %, a growth rate of the SiGeC layer is proportional to temperature. The growth rate of the SiGeC layer may be examined like the growth rate of Si. At 600° C., a growth rate of 20 Å/min or less is required to obtain about 0.9 atomic % of substituted carbon. At 700° C., the growth rate is 20-80 Å/min according to the amount of substituted carbon; however, the amount of the substituted carbon is about 0.65 atomic % or less. At 650° C., the amount of substituted carbon is about 0.65-1.05 atomic % and a growth rate is about 17-40 Å/min.

When the growth temperature of the SiGeC layer/region is relatively low, the amount of substituted carbon is large but the growth rate is slow. On the contrary, when the growth temperature is relatively high, the amount of substituted carbon is small but a growth rate is high. For the SiGeC layer according to embodiments of the invention, the amount of substituted carbon is preferably 0.5-2.0 atomic % and a corresponding growth temperature is preferably 550-700° C.

FIG. 3 is a graph illustrating a growth rate of the SiGeC layer according to a concentration of Ge. Specifically, the graph illustrates the growth rate according to the Ge concentration when the amount of substituted carbon is fixed at 1 atomic %. Referring to FIG. 3, the SiGeC layer is formed at 650° C. using SiH₄ or GeH₄ as a source gas. The growth rate of the SiGeC layer and the Ge concentration increase when a flow rate (sccm) of GeH₄ increases. For example, when the Ge concentration is 0%, the growth rate of the SiGeC layer is about 50 Å/min or less. When the Ge concentration is 7 atomic %, the growth rate of the SiGeC layer is about 250 Å/min. That is, the growth rate of the SiGeC layer increases in proportion to the Ge concentration. When the growth rate increases, the probability of intrusion of carbon into a space between Si lattice sites decreases because a migration time of atoms in the SiGeC layer is reduced. However, since a Ge atom is larger in size than a Si atom, a stress generated by the Ge atoms acts as the compressive stress on the channel region. Accordingly, the concentration of the Ge atoms needs to be limited within a predetermined range so as to obtain a resulting tensile stress. In the embodiments, an atomic ratio of Ge/C is preferably 12 or less and a Ge concentration is preferably 6-24 atomic %.

Consequently, it is preferable that an atomic ratio of Ge/C in the SiGeC layer is 12 or less at 550-700° C. That is, the substituted carbon can be induced by formation of the SiGeC layer at 550-700° C. Also, the growth rate of the SiGeC layer can be maximized by reduction of the atomic ratio of Ge/C to a range between 12 and zero. Accordingly, a net tensile stress is applied to the channel region by the SiGeC layer thereby improving the mobility of carriers, particularly electrons.

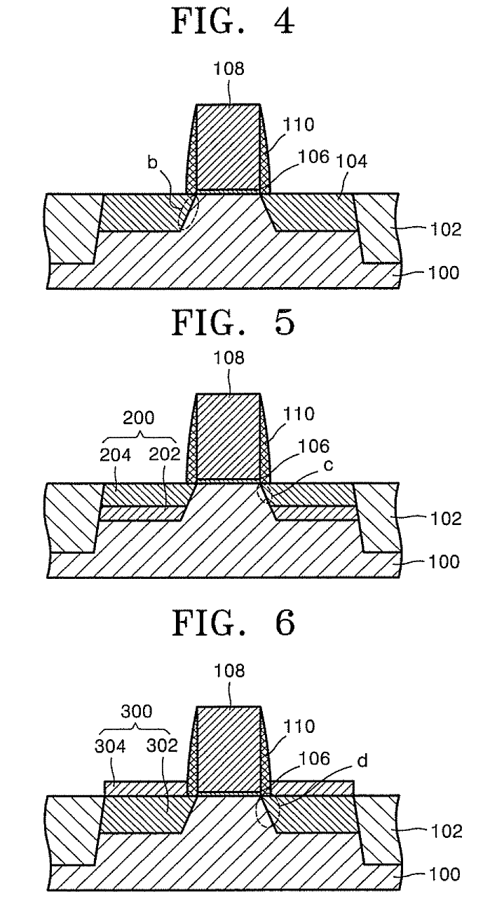

FIGS. 4 through 6 are sectional views illustrating a method of manufacturing a semiconductor device according to an embodiment of the present invention. Referring to FIG. 4, a semiconductor substrate 100, including a limited channel region, is formed with an active region defined by a device isolating layer 102. Thereafter, a gate electrode 108 is formed on the channel region of the semiconductor substrate 100 with a gate insulating layer 106 interposed therebetween. Here, insulating spacers 110 may be further formed on sidewalls of the gate electrode 108. The semiconductor substrate 100 at the both sides of the gate electrode 108 is etched using the gate electrode 108 as an etch mask, thereby forming a recessed region. Thereafter, a first SiGeC layer 104 is formed in the recessed region. The first SiGeC layer 104 is formed using a silicon-based source gas. The Si-based source gas is at least one selected from a group consisting of SiCl₂H₂, SiH₄, and Si₂H₆. Ge source gas for forming the first SiGeC layer 104 may be GeH₄. At this time, HCl gas may be further used to obtain a suitable growth selectivity ratio on the surfaces of the spacer 110 and on the device isolation layer 102 relative to the first SiGeC layer 104 in the recessed region.

A pressure due to the source gases in the first SiGeC layer 104 may be 1-100 Torr. It is preferable that the pressure due to the source gases is low, for example, about 20 Torr, so as to obtain a desired growth selectivity ratio. As described above, the growth temperature of the first SiGeC layer 104 is preferably 550-700° C. Also, when dopants are injected in-situ during the formation of the first SiGeC layer 104, a P-N junction with an abrupt dopant profile can be formed because carbon inhibits penetration of the injected dopants. Accordingly, the first SiGeC layer 104 may be formed while dopants such as PH₃ and AsH₃ are injected in-situ. In the semiconductor device in FIG. 4, the first SiGeC layer 104 constitutes a source/drain region, and electron mobility in the channel increases by application of the tensile stress applied to a portion “b” contacting with the channel region.

Referring to FIG. 5, after the formation of the gate electrode 108, dopants are injected into the semiconductor substrate 100 at both sides of the gate electrode 108 to form a doped region 202. Thereafter, an upper portion of the doped region 202 at both sides of the gate electrode 108 is etched using the gate electrode 108 as an etch mask, thereby forming a recessed region. A second SiGeC layer 204 is formed in the recessed region. The semiconductor device in FIG. 5 includes a source/drain region 200 where the doped region 202 and the second SiGeC layer 204 are stacked. Accordingly, a tensile stress is applied to a portion “c” contacting with the channel region to increase the electron mobility therein. Here, the method of forming the second SiGeC layer 204 is similar to the method of forming the first SiGeC layer 104.

Referring to FIG. 6, after the formation of the gate electrode 108, dopants are injected onto the semiconductor substrate 100 at the both sides of the gate electrode 108 to form a doped region 302. Thereafter, a third SiGeC layer 304 is formed on the semiconductor substrate 100 at the both sides of the gate electrode 108. The semiconductor device in FIG. 6 includes a source/drain region 300 where the doped region 302 and the third SiGeC layer 304 are stacked. Accordingly, a tensile stress is applied to a portion “d” contacting with the channel region to increase the electron mobility therein. Here, the method of forming the third SiGeC layer 304 is similar to the method of forming the first SiGeC layer 104.

In the drawings and specification, there have been disclosed typical preferred embodiments of the invention and, although specific terms are employed, they are used in a generic and descriptive sense only and not for purposes of limitation, the scope of the invention being set forth in the following claims.

1. A field effect transistor, comprising:
a substrate having a semiconductor channel region therein;
a gate electrode on the channel region; and
a SiGeC region forming a semiconductor junction with the channel region, said SiGeC region having a Ge/C atomic ratio of less than about 12 and greater than about zero and a sufficient concentration of substitutional C atoms therein to thereby induce a net tensile stress in at least a portion of the channel region.

2. The transistor of claim 1, wherein a concentration of C atoms in said SiGeC region is in a range between about 0.5 atomic % and about 2.0 atomic %.

3. The transistor of claim 2, wherein a concentration of Ge atoms in said SiGeC region is in a range between about 6 atomic % and about 24 atomic %.

4. The transistor of claim 1, wherein a concentration of Ge atoms in said SiGeC region is in a range between about 6 atomic % and about 24 atomic %.

5. The transistor of claim 1, wherein said SiGeC region is doped with N-type dopants.

6. A field effect transistor, comprising:
a substrate having a semiconductor channel region therein;
an insulated gate electrode on the channel region; and
a SiGeC source region forming a P-N junction with the channel region, said SiGeC source region having a sufficient concentration of substitutional C atoms therein to thereby induce a net tensile stress in at least a portion of the channel region extending opposite said insulated gate electrode.

7. The transistor of claim 6, wherein a Ge/C atomic ratio in said SiGeC source region is in a range between about 0 and about 12.

8. The transistor of claim 6, wherein a concentration of C atoms in said SiGeC source region is in a range between about 0.5 atomic % and about 2.0 atomic %.

9. The transistor of claim 8, wherein a concentration of Ge atoms in said SiGeC source region is in a range between about 6 atomic % and about 24 atomic %.

10. A method of forming a field effect transistor, comprising the steps of:
forming a gate electrode on a surface of a semiconductor substrate having a semiconductor channel region therein extending opposite the gate electrode;
selectively etching the surface of the semiconductor substrate to define source and drain region trenches therein on opposite sides of the channel region; and
forming source and drain regions comprising SiGeC in the source and drain region trenches, respectively, said source and drain regions having a sufficient concentration of substitutional C atoms therein to thereby induce a net tensile stress in portions of the channel region extending opposite the gate electrode.

11. The method of claim 10, wherein a Ge/C atomic ratio in the SiGeC within the source and drain regions is in a range between about 0 and about 12.

12. The method of claim 10, wherein forming source and drain regions comprises depositing SiGeC regions into the source and drain region trenches at a temperature in a range from about 550° C. to about 700° C.

13. The method of claim 12, wherein depositing SiGeC regions into the source and drain region trenches comprises depositing SiGeC into the source and drain region trenches while simultaneously injecting source and drain region dopants into the deposited SiGeC.

14. The method of claim 12, wherein forming source and drain regions comprising SiGeC is preceded by a step of injecting source and drain region dopants into the semiconductor substrate.

15. The method of claim 12, wherein depositing SiGeC regions into the source and drain region trenches comprises depositing SiGeC using a silicon-based source gas selected from a group consisting of SiCl₂H₂, SiH₄ and Si₂H₆.

16. The method of claim 15, wherein depositing SiGeC regions into the source and drain region trenches comprises depositing SiGeC using a germanium-based source gas comprising GeH₄.

17. The method of claim 15, wherein depositing SiGeC into the source and drain region trenches comprises exposing the trenches to an HCl gas.
